(19) United States
(12) Patent Application Publication
(10) Pub. No.: US 2018/0166259 A1
(43) Pub. Date: Jun. 14, 2018

(54) MOUNTING TABLE AND PLASMA PROCESSING APPARATUS

(71) Applicant: Tokyo Electron Limited, Tokyo (JP)

(72) Inventor: Takehiro Ueda, Kurokawa-gun (JP)

(21) Appl. No.: 15/833,060

(22) Filed: Dec. 6, 2017

(30) Foreign Application Priority Data
Dec. 8, 2016 (JP) 2016-238399

(51) Int. Cl. H01J 37/32; H01L 21/683

(52) U.S. Cl. CPC H01J 37/32642; H01L 21/67069; H01L 21/6833; H01J 37/32724

(57) ABSTRACT

Non-uniformity of temperature of a focus ring can be improved by reducing holes which hamper a heat transfer from the focus ring to a base. A mounting table includes the base configured to place a processing target object thereon; the focus ring provided on the base to surround a region on which the processing target object is placed; a connecting member provided with a through hole and configured to connect the base to a member provided below the base by being inserted into an insertion hole formed at a region of the base which corresponds to a lower portion of the focus ring; and a lifter pin provided at the base such that the lifter pin is allowed to be protruded from the insertion hole by being inserted into the through hole of the connecting member, and configured to raise the focus ring by being protruded from the insertion hole.

### CROSS-REFERENCE TO RELATED APPLICATION

This application claims the benefit of Japanese Patent Application No. 2016-238399 filed on Dec. 8, 2016, the entire disclosures of which are incorporated herein by reference.

### TECHNICAL FIELD

The embodiments described herein pertain generally to a mounting table and a plasma processing apparatus.

### BACKGROUND

In a plasma processing apparatus configured to perform a plasma processing such as film formation or etching, a processing target object is placed on a mounting table provided within a processing vessel. The mounting table has, for example, a base, a focus ring, and so forth. The base has a region on which the processing target object is placed. The focus ring is provided on the base to surround the region on which the processing target object is placed. As the focus ring is provided on the base to surround the region on which the processing target objet is placed, uniformity of a plasma distribution in the vicinity of an edge portion of the processing target objet is improved.

While performing the etching with plasma, however, the focus ring is also etched gradually along with the processing target object. If the focus ring is etched, the uniformity of the plasma distribution at the edge portion of the processing target object is deteriorated. Accordingly, an etching rate at the edge portion of the processing target object is changed, so that device characteristics are degraded. Thus, it is important to maintain a height of the focus ring to suppress the deterioration of the uniformity of the plasma distribution.

As a way to maintain the height of the focus ring, there is known a technique of measuring a consumption amount of the focus ring and raising the focus ring based on the measurement result. Further, as a method of raising the focus ring, there is known a technique of inserting a lifter pin protrusibly/retractably into a through hole formed at a region of the base which corresponds to a lower portion of the focus ring and raising the focus ring by protruding the lifter pin.
Patent Document 1: Japanese Patent Publication No. 3,388,228
Patent Document 2: Japanese Patent Laid-open Publication No. 2007-258417
Patent Document 3: Japanese Patent Laid-open Publication No. 2011-054933
Patent Document 4: Japanese Patent Laid-open Publication No. 2016-146472

At the region of the base which corresponds to the lower portion of the focus ring, however, the through hole for the lifter pin and an insertion hole through which a screw member is inserted may be independently provided. The screw member is inserted into the insertion hole and connects the base to a member provided below the base. The through hole for the lifter pin and the insertion hole for the screw member are spaces having lower heat conductivity as compared to that of the base. Therefore, if the through hole for the lifter pin and the insertion hole for the screw member are independently provided at the region of the base which corresponds to the lower portion of the focus ring, a heat transfer from the focus ring to the base may be hampered by both the through hole for the lifter pin and the insertion hole for the screw member. As a result, singularity of temperature may be locally generated at portions of the focus ring corresponding to the through hole for the lifter pin and the insertion hole for the screw member, resulting in deterioration of temperature uniformity of the focus ring.

Meanwhile, it is known that if the temperature uniformity of the focus ring is deteriorated, uniformity in the consumption amount of the focus ring is also deteriorated while performing the etching with the plasma, so that the etching rate at the edge portion of the processing target object is varied. Thus, it is desirable that a temperature of the focus ring is uniform to maintain the etching rate at the edge portion of the processing target object. For the purpose, it is required to suppress non-uniformity of the temperature of the focus ring by reducing the holes which hamper the heat transfer from the focus ring to the base.

### SUMMARY

In one exemplary embodiment, there is provided a mounting table including a base configured to place a processing target object thereon; a focus ring provided on the base to surround a region on which the processing target object is placed; a connecting member provided with a through hole and configured to connect the base to a member provided below the base by being inserted into an insertion hole formed at a region of the base which corresponds to a lower portion of the focus ring; and a lifter pin provided at the base such that the lifter pin is allowed to be protruded from the insertion hole by being inserted into the through hole of the connecting member, and configured to raise the focus ring by being protruded from the insertion hole.

According to the exemplary embodiment, it is possible to improve non-uniformity of the temperature of the focus ring by reducing holes which hamper a heat transfer from the focus ring to the base.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a longitudinal cross sectional view illustrating a schematic configuration of a plasma processing apparatus according to a first exemplary embodiment;

FIG. 2 is a perspective view illustrating a configuration of a mounting table according to the first exemplary embodiment;

FIG. 3 is a cross sectional view illustrating the configuration of the mounting table according to the first exemplary embodiment;

FIG. 4 is a diagram illustrating a heat transfer in a configuration where a through hole for a lifter pin and an insertion hole for a screw member are independently provided at a peripheral region of a base;

FIG. 5 is a diagram for describing a relationship between a temperature of a focus ring and an etching rate;

FIG. 6 is a diagram illustrating a heat transfer in a configuration where the through hole for the lifter pin is removed from the peripheral region of the base;

FIG. 7 is a cross sectional view illustrating a configuration of a mounting table according to a second exemplary embodiment;

FIG. 8 is a plan view illustrating a configuration of a heating member shown in FIG. 7; and

FIG. 9 is a cross sectional view illustrating a configuration of a mounting table according to a third exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a mounting table and a plasma processing apparatus according to exemplary embodiments will be explained in detail with reference to the accompanying drawings. In the drawings, same or corresponding parts will be assigned same reference numerals.

### First Exemplary Embodiment

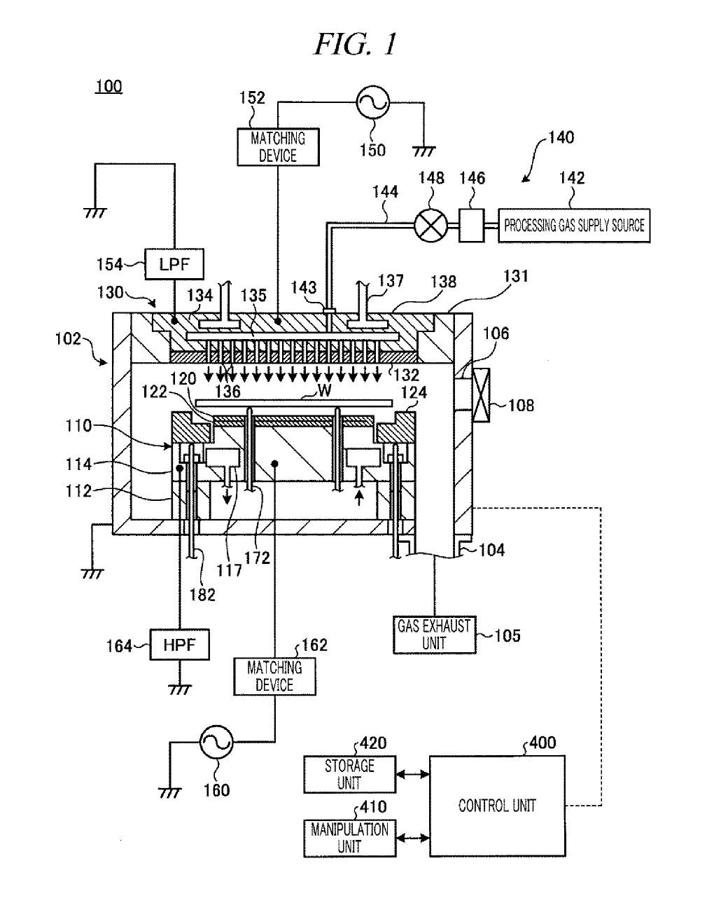

FIG. 1 is a longitudinal cross sectional view illustrating a schematic configuration of a plasma processing apparatus 100 according to a first exemplary embodiment. Here, the description will be provided for an example case where a substrate processing apparatus is implemented by the single plasma processing apparatus 100 of a parallel plate type.

The plasma processing apparatus 100 includes a cylindrical processing vessel 102 made of, for example, aluminum having an anodically oxidized (alumite-treated) surface. The processing vessel 102 is grounded. A substantially columnar mounting table 110 configured to place thereon a wafer W as a processing target object is provided at a bottom portion of the processing vessel 102. The mounting table 110 has a base 114. The base 114 is made of a conductive metal and is configured as a lower electrode. The base 114 is supported by an insulating member 112. The insulating member 112 is a cylindrical member placed at the bottom portion of the processing vessel 102.

The base 114 has a region on which the wafer W is placed; and a region surrounding the region on which the wafer W is placed. In the following, the region on which the wafer W is placed will be referred to as “placing region,” and the region surrounding this placing region will be referred to as “peripheral region.” In the present exemplary embodiment, the placing region of the base 114 is higher than the peripheral region thereof. An electrostatic chuck 120 is provided on the placing region of the base 114. The electrostatic chuck 120 includes an insulating material and an electrode 122 embedded in the insulating material. A DC voltage of, e.g., 1.5 kV is applied to the electrostatic chuck 120 from a non-illustrated DC power supply connected to the electrode 122. Accordingly, the wafer W is electrostatically attracted to and held by the electrostatic chuck 120.

A focus ring 124 is provided on the peripheral region of the base 114. By providing the focus ring 124 on the peripheral region of the base 114, uniformity of a plasma distribution in the vicinity of an edge portion of the wafer W is improved.

The insulating member 112, the base 114 and the electrostatic chuck 120 are provided with a non-illustrated gas passageway for supplying a heat transfer medium (e.g., a backside gas such as a He gas) to a rear surface of the wafer W placed on the placing region of the base 114. Heat is transferred between the base 114 and the wafer W by this heat transfer medium, and the wafer W is maintained at a preset temperature.

A coolant path 117 is formed within the base 114. A coolant cooled to a preset temperature is supplied into and circulated through the coolant path 117 by a non-illustrated chiller unit.

Further, the base 114 is provided with lifter pins 172 configured to be protrusible from the placing region of the base 114. The lifter pins 172 are driven by a non-illustrated driving mechanism. The lifter pins 172 are protruded from the placing region of the base 114 to raise the wafer W.

Furthermore, the base 114 is also provided with lifter pins 182 configured to be protrusible from the peripheral region of the base 114. The lifter pins 182 are driven by a non-illustrated driving mechanism. As the lifter pins 182 are protruded from the peripheral region of the base 114, the focus ring 124 is raised. Details of the mounting table 110 including the base 114, the focus ring 124 and the lifter pins 182 will be discussed later.

An upper electrode 130 is provided above the base 114, facing the base 114. A space formed between the upper electrode 130 and the base 114 is a plasma generation space. The upper electrode 130 is supported at an upper portion of the processing vessel 102 with an insulating shield member 131 therebetween.

The upper electrode 130 mainly includes an electrode plate 132; and an electrode supporting member 134 configured to support the electrode plate 132 in a detachable manner. The electrode plate 132 is made of, by way of non-limiting example, quartz, and the electrode supporting member 134 is made of a conductive material such as, but not limited to, aluminum having an alumite-treated surface.

The electrode supporting member 134 is provided with a processing gas supply unit 140 configured to introduce a processing gas from a processing gas supply source 142 into the processing vessel 102. The processing gas supply source 142 is connected to a gas inlet opening 143 of the electrode supporting member 134 via a gas supply line 144.

The gas supply line 144 is provided with a mass flow controller (MFC) 146 and an opening/closing valve 148 in sequence from the upstream side, as illustrated in FIG. 1, for example. Here, a flow control system (FCS) may be provided instead of the MFC. A fluorocarbon gas (CₓF_{y}) such as, but not limited to, a C₄F₈ gas is supplied from the processing gas supply source 142 as the processing gas for etching.

The processing gas supply source 142 is configured to supply, for example, an etching gas for plasma etching. Further, though only one processing gas supply system including the gas supply line 144, the opening/closing valve 148, the mass flow controller 146 and the processing gas supply source 142 is illustrated in FIG. 1, the plasma processing apparatus 100 is actually equipped with a multiple number of processing gas supply systems. For example, etching gases such as CF₄, O₂, N₂ and CHF₃ are supplied into the processing vessel 102 at independently controlled flow rates.

The electrode supporting member 134 is provided with, for example, a substantially cylindrical gas diffusion space 135 in which the processing gas introduced from the gas supply line 144 can be uniformly diffused. Further, a multiple number of gas discharge holes 136 is formed in a bottom portion of the electrode supporting member 134 and the electrode plate 132 to discharge the processing gas from the gas diffusion space 135 into the processing vessel 102. The processing gas diffused in the gas diffusion space 135 can be uniformly discharged toward the plasma generation space from the gas discharge holes 136. In this point of view, the upper electrode 130 serves as a shower head configured to supply the processing gas.

The upper electrode 130 is equipped with an electrode supporting member temperature control unit 137 capable of controlling a temperature of the electrode supporting member 134 to a preset temperature. For example, the electrode supporting member temperature control unit 137 is configured to circulate a temperature control medium into a temperature control medium path 138 provided within the electrode supporting member 134.

A gas exhaust line 104 is connected to a bottom portion of the processing vessel 102, and the gas exhaust line 104 is connected to a gas exhaust unit 105. The gas exhaust unit 105 includes a vacuum pump such as a turbo molecular pump and is configured to adjust the inside of the processing vessel 102 into a preset decompressed atmosphere. Further, a carry-in/out opening 106 for the wafer W is provided at a sidewall of the processing vessel 102, and a gate valve 108 is provided at the carry-in/out opening 106. When a carry-in/out of the wafer W is performed, the gate valve 108 is opened. The wafer W is carried in and out through the carry-in/out opening 106 by a non-illustrated transfer arm or the like.

The upper electrode 130 is connected to a first high frequency power supply 150, and a power feed line thereof is provided with a first matching device 152 inserted therein. The first high frequency power supply 150 is configured to output a high frequency power for plasma generation having a frequency ranging from 50 MHz to 150 MHz. By applying the power having such a high frequency to the upper electrode 130, plasma having a high density and a desirable dissociation state can be generated within the processing vessel 102. Therefore, a plasma processing can be performed under a lower pressure condition. Desirably, a frequency of the output power of the high frequency power supply 150 may be in a range from 50 MHz to 80 MHz, typically, and may be adjusted to 60 MHz or thereabout.

The base 114 configured as the lower electrode is connected to a second high frequency power supply 160, and a power feed line thereof is provided with a second matching device 162 inserted therein. The second high frequency power supply 160 is configured to output a high frequency bias power having a frequency ranging from several hundreds of kHz to several tens of MHz. A frequency of the output power of the second high frequency power supply 160 is typically adjusted to, by way of non-limiting example, 2 MHz, 13.56 MHz or the like.

Further, the base 114 is also connected with a high pass filter (HPF) 164 configured to filter a low frequency current flowing into the base 114 from the first high frequency power supply 150. The upper electrode 130 is connected to a low pass filter (LPF) configured to filter a high frequency current flowing into the upper electrode 130 from the second high frequency power supply 160.

The plasma processing apparatus 100 is connected to a control unit (overall control device) 400, and individual components of the plasma processing apparatus 100 are controlled by the control unit 400. Further, the control unit 400 is connected to a manipulation unit 410 including a keyboard through which an operator inputs commands and the like to manage the plasma processing apparatus 100, a display configured to visually display an operational status of the plasma processing apparatus 100, and so forth.

Moreover, the control unit 400 is also connected with a storage unit 420 storing therein programs for implementing various processings (a processing chamber state stabilizing processing to be described later, etc., in addition to a plasma processing upon the wafer W) performed in the plasma processing apparatus 100 under the control of the control unit 400, processing conditions (recipes) required to execute the programs, and so forth.

The storage unit 420 stores therein, for example, a multiple number of processing conditions (recipes). These processing conditions are data of multiple parameter values such as control parameters for controlling the individual components of the plasma processing apparatus 100, setting parameters, and so forth. Each processing condition has parameter values such as, but not limited to, a flow rate ratio of the processing gases, a pressure within the processing chamber and the high frequency power.

These programs and the processing conditions may be recorded in a hard disk or a semiconductor memory, or may be set to a preset position of the storage unit 420 while being recorded in a computer-readable portable recording medium such as a CD-ROM, a DVD, or the like.

The control unit 400 reads out a required program and a required processing condition from the storage unit 420 in response to an instruction from the manipulation unit 410 or the like, and then, controls the individual components, so that a required processing is performed in the plasma processing apparatus 100. Further, the processing condition can be edited by using the manipulation unit 410.

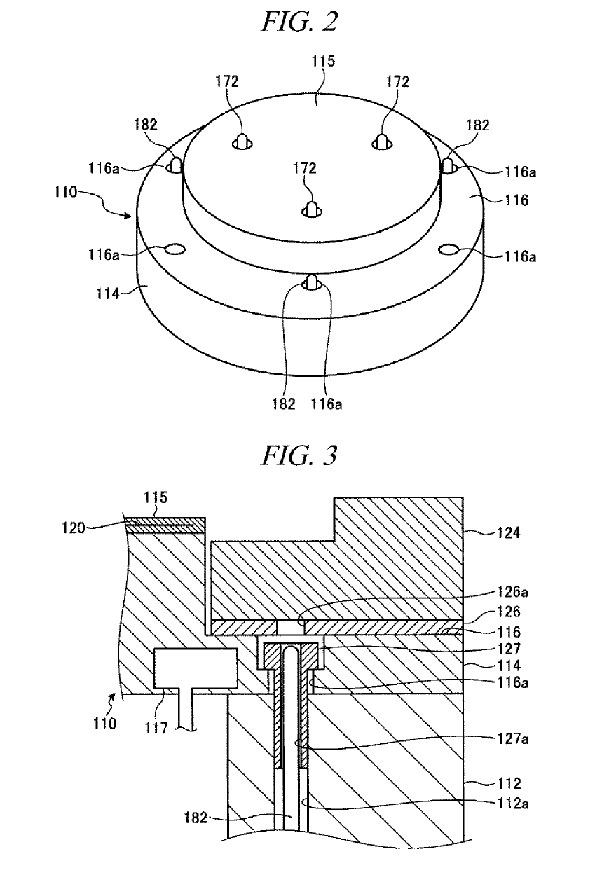

Now, the mounting table 110 will be explained in detail. FIG. 2 is a perspective view illustrating a configuration of the mounting table 110 according to a first exemplary embodiment. FIG. 3 is a cross sectional view illustrating the configuration of the mounting table 110 according to the first exemplary embodiment. In FIG. 2, the focus ring 124 and the electrostatic chuck 120 are omitted for the simplicity of explanation. Further, though the base 114 and the electrostatic chuck 120 are illustrated separately in the example of FIG. 3, the base 114 and the electrostatic chuck 120 may be sometimes referred to as “base 114” together. When referring to the base 114 and the electrostatic chuck 120 together as the “base 114”, a top surface of the electrostatic chuck 120 corresponds to a placing region 115 of the base 114.

As depicted in FIG. 2 and FIG. 3, the base 114 has the placing region 115 and a peripheral region 116. The wafer W is placed on the placing region 115. The focus ring 124 is placed on the peripheral region 116 with a heat transfer sheet 126 therebetween. The heat transfer sheet 126 is extensible and contractible and is provided with a through hole 126a. The peripheral region 116 of the base 114 is a region of the base 114 which corresponds to a lower portion of the focus ring 124.

Insertion holes 116a are formed at the peripheral region 116 of the base 114, and screw members 127 are inserted into the insertion holes 116a. Meanwhile, the insulating member 112 under the base 114 is provided with screw holes 112a which are formed through the insulating member 112 in a thickness direction thereof, and the screw members 127 inserted in the insertion holes 116a are screwed into the screw holes 112a. As the screw members 127 inserted in the insertion holes 116a are screwed into the screw holes 112a of the insulating member 112, the base 114 and the insulating member 112 are connected by the screw members 127. In the present exemplary embodiment, since the base 114 and the insulating member 112 are connected by the screw members 127, the same number of insertion holes 116a as the screw members 127 are formed at the peripheral region 116 of the base 114, as illustrated in FIG. 2.

Each screw member 127 is provided with a through hole 127a extended along a central axis of the corresponding screw member 127. The lifter pins 182 are inserted into the through holes 127a of the screw members 127. The lifter pins 182 are provided at the base 114 such that they can be inserted into the through holes 127a of the screw members 127 to be protruded from the insertion holes 116a. The lifter pins 182 are protruded from the insertion holes 116a and raise the focus ring 124. To be specific, when the lifter pins 182 are protruded from the insertion holes 116a, the lifter pins 182 come into contact with the lower portion of the focus ring 124 after passing through the through holes 126a of the heat transfer sheet 126, so that the focus ring 124 is raised. The heat transfer sheet 126 is expanded to fill a gap between the base 114 and the focus ring 124 when the focus ring 124 is raised.

Further, desirably, the number of the lifter pins 182 provided at the base 114 may be three or more to raise the focus ring 124 horizontally. In FIG. 2, as an example, three lifter pins 182 are shown.

Meanwhile, at the region of the base 114 which corresponds to the lower portion of the focus ring 124 (that is, the peripheral region 116 of the base 114), through holes for the lifter pins 182 and the insertion holes 116a for the screw members 127 may be provided independently. The through holes for the lifter pins 182 and the insertion holes 116a for the screw members 127 are spaces having lower heat conductivity as compared to that of the base 114. Therefore, if the through holes for the lifter pins 182 and the insertion holes 116a for the screw members 127 are independently provided at the peripheral region 116 of the base 114, the heat transfer from the focus ring 124 to the base 114 is hindered by both the through holes for the lifter pins 182 and the insertion holes 116a for the screw members 127. As a result, singularity of temperature may be locally generated at portions of the focus ring 124 corresponding to the through holes for the lifter pins 182 and the insertion holes 116a for the screw members 127, so that temperature uniformity of the focus ring 124 is deteriorated.

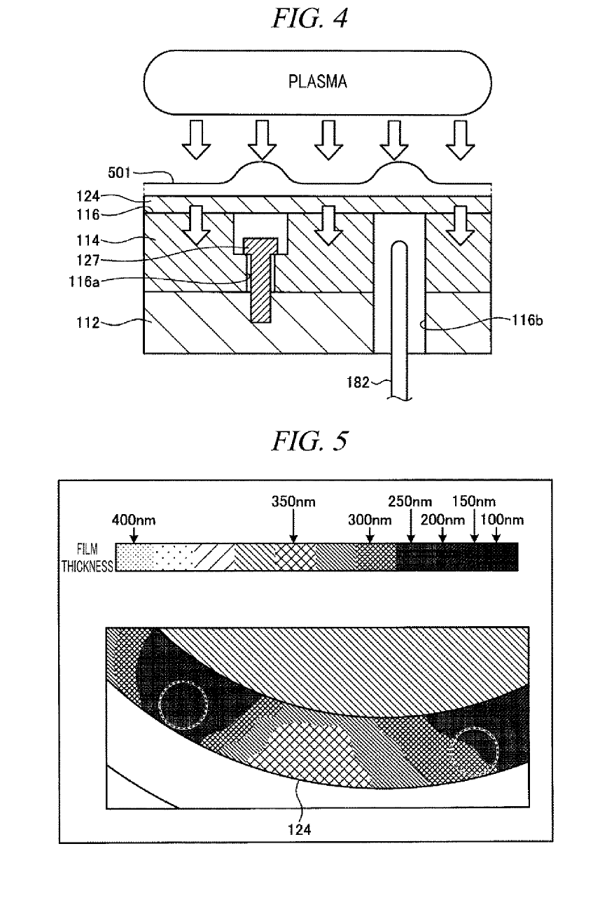

FIG. 4 is a diagram illustrating a state of a heat transfer in a configuration where a through hole 116b for the lifter pin 182 and the insertion hole 116a for the screw member 127 are provided independently at the peripheral region 116 of the base 114. Further, in FIG. 4, the heat transfer sheet 126 between the base 114 and the focus ring 124 is omitted for the simplicity of explanation. In FIG. 4, arrows indicate a flow of heat. Further, in FIG. 4, a curved line 501 indicates a distribution of a temperature of the focus ring 124.

The temperature of the focus ring 124 is determined by a heat transfer from the plasma to the focus ring 124 and a heat transfer from the focus ring 124 to the base 114. As depicted in FIG. 4, if the through hole 116b for the lifter pin 182 and the insertion hole 116a for the screw member 127 are independently provided at the peripheral region 116 of the base 114, the heat transfer from the focus ring 124 to the base 114 is hindered by both the through hole 116b for the lifter pin 182 and the insertion hole 116a for the screw member 127. Accordingly, as indicated by the curved line 501, the temperature of the focus ring 124 rises locally at portions thereof corresponding to the through hole 116b for the lifter pin 182 and the insertion hole 116a for the screw member 127. As a result, the temperature uniformity of the focus ring 124 is deteriorated. Here, if the temperature uniformity of the focus ring 124 is deteriorated, uniformity in the consumption amount of the focus ring 124 while performing the etching with the plasma may also be deteriorated, so that an etching rate at the edge portion of the wafer W is varied.

FIG. 5 is a diagram for describing a relationship between the temperature of the focus ring 124 and the etching rate. FIG. 5 shows a film thickness of a deposit when a deposition processing is performed on the focus ring 124 by using plasma. Further, in FIG. 5, dashed-lined circles indicate the portions of the focus ring 124 corresponding to the through hole 116b for the lifter pin 182 and the insertion hole 116a for the screw member 127.

As depicted in FIG. 5, the film thickness of the deposit at the portions of the focus ring 124 corresponding to the through hole 116b for the lifer pin 182 and the insertion hole 116a for the screw member 127 is found to be thinner than the film thickness of the deposit at the other portions of the focus ring 124. It is deemed to be because the deposit is suppressed from adhering as the temperature of the focus ring 124 rises locally at the portions of the focus ring 124 corresponding to the through hole 116b for the lifter pin 182 and the insertion hole 116a for the screw member 127. As the film thickness of the deposit is reduced, the consumption amount of the focus ring 124 is increased while performing the etching with the plasma, which results in a large variation of the etching rate at the edge portion of the wafer W. In view of this, to maintain the etching rate at the edge portion of the wafer W, it is desirable that the temperature of the focus ring 124 is uniform.

For the purpose, in the present exemplary embodiment, it is attempted to suppress the non-uniformity of the temperature of the focus ring 124 by removing the hole which hamper the heat transfer from the focus ring 124 to the base 114. To elaborate, according to the present exemplary embodiment, the through hole 116b for the lifter pin 182 (see FIG. 4) is removed from the peripheral region 116 of the base 114, and the lifter pin 182 is inserted into the through hole 127a of the screw member 127.

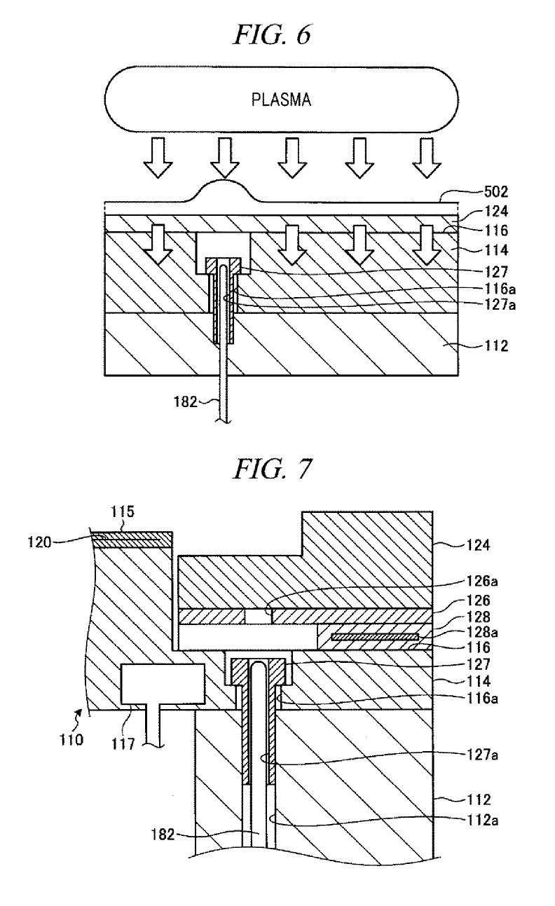

FIG. 6 is a diagram illustrating a state of a heat transfer in a configuration where the through hole 116b for the lifter pin 182 is removed from the peripheral region 116 of the base 114. Further, in FIG. 6, the heat transfer sheet 126 between the base 114 and the focus ring 124 is omitted for the simplicity of explanation. In FIG. 6, arrows indicate a flow of heat. Further, in FIG. 6, a curved line 502 indicates a distribution of the temperature of the focus ring 124.

The temperature of the focus ring 124 is determined by a heat transfer from the plasma to the focus ring 124 and a heat transfer from the focus ring 124 to the base 114. As depicted in FIG. 6, in the present exemplary embodiment, by inserting the lifter pin 182 into the through hole 127a of the screw member 127, the through hole 116b for the lifter pin 182 is removed from the peripheral region 116 of the base 114. That is, in the present exemplary embodiment, the number of the holes that impede the heat transfer from the focus ring 124 to the base 114 is reduced as compared to the configuration in which the through hole 116b for the lifter pin 182 and the insertion hole 116a for the screw member 127 are independently provided at the peripheral region 116 of the base 114 (that is, the configuration shown in FIG. 4). Thus, as indicated by the curved line 502, in the present exemplary embodiment, the singularity of the temperature, which is locally generated at the focus ring 124, is reduced as compared to the configuration shown in FIG. 4. As a consequence, the non-uniformity of the temperature of the focus ring 124 is improved.

As stated above, according to the present exemplary embodiment, the lifter pin 182 is inserted into the through hole 127a of the screw member 127 which is inserted into the insertion hole 116a formed at the peripheral region 116 of the base 114, and the focus ring 124 is raised by the lifter pin 182 protruded from the insertion hole 116a. Thus, according to the exemplary embodiment, the through hole for the lifter pin 182 can be removed from the peripheral region 116 of the base 114. As a result, the hole which hampers the heat transfer from the focus ring 124 to the base 114 can be reduced, so that the non-uniformity of the temperature of the focus ring 124 can be suppressed.

Moreover, according to the present exemplary embodiment, the focus ring 124 is provided on the base 114 with the extensible/contractible heat transfer sheet 126 having the through hole 126a therebetween. When the lifter pin 182 is protruded from the insertion hole 116a to raise the focus ring 124, the lifter pin 182 passes through the through hole 126a of the heat transfer sheet 126 and comes into contact with the lower portion of the focus ring 124. As the focus ring 124 is raised, the heat transfer sheet 126 is extended to fill the gap between the base 114 and the focus ring 124. Therefore, even when the focus ring 124 is raised, the heat transfer from the focus ring 124 to the base 114 can be continued while improving the non-uniformity of the temperature of the focus ring 124.

In addition, according to the present exemplary embodiment, the coolant path 117 is formed within the base 114. Accordingly, it is possible to perform the heat transfer from the focus ring 124 to the base 114 efficiently while improving the non-uniformity of the temperature of the focus ring 124.

### Second Exemplary Embodiment

A second exemplary embodiment is characterized in that the uniformity of the temperature of the focus ring is improved by providing a heating member between the base and the focus ring.

Since a configuration of a plasma processing apparatus according to the second exemplary embodiment is the same as the configuration of the plasma processing apparatus 100 of the first exemplary embodiment, redundant description thereof will be omitted here. In the second exemplary embodiment, a configuration of a mounting table 110 is different from that of the first exemplary embodiment.

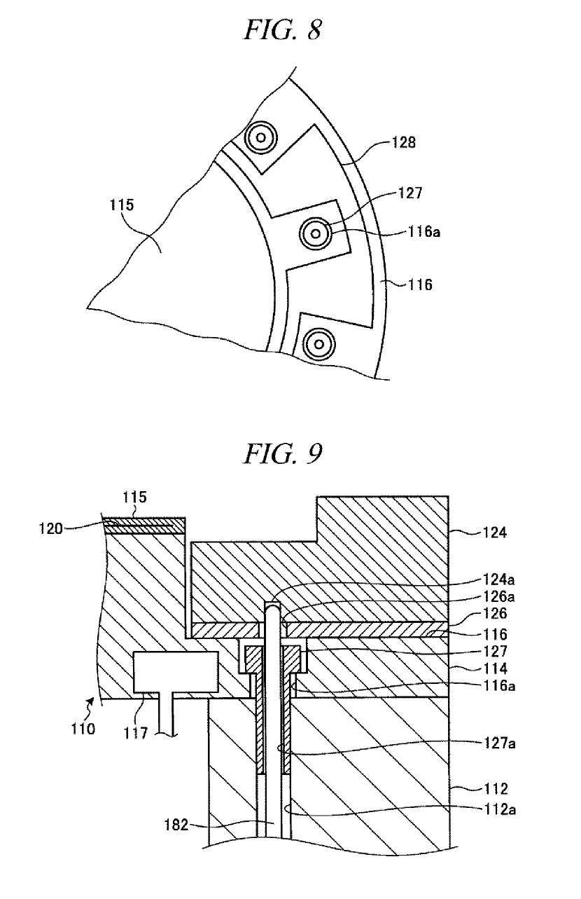

FIG. 7 is a cross sectional view illustrating the configuration of the mounting table 110 according to the second exemplary embodiment. FIG. 8 is a plan view illustrating a configuration of a heating member 128 shown in FIG. 7. In FIG. 7, the same parts as those of FIG. 3 will be assigned same reference numerals, and redundant description will be omitted. Further, in FIG. 8, the focus ring 124 and the heat transfer sheet 126 are omitted for the simplicity of explanation.

As depicted in FIG. 7, in the second exemplary embodiment, the heating member 128 is provided between the base 114 and the focus ring 124. As shown in FIG. 8, the heating member 128 is configured to cover, in the region of the base 114 which corresponds to the lower portion of the focus ring 124 (that is, the peripheral region 116 of the base 114), a region except an insertion hole 116a. The heating member 128 includes a main body portion formed of an insulating material; and a heater portion 128a formed within the main body portion, and is configured to heat a portion of the focus ring 124 other than the portion corresponding to the insertion hole 116a for the screw member 127.

According to the second exemplary embodiment, the portion of the focus ring 124 other than the portion corresponding to the insertion hole 116a for the screw member 127 is heated by the heating member 128. Here, since the heat transfer from the focus ring 124 to the base 114 is impeded by the insertion hole 116a for the screw member 127, a temperature of the portion of the focus ring 124 corresponding to the insertion hole 116a for the screw member 127 rises locally. By heating the portion of the focus ring 124 other than the portion corresponding to the insertion hole 116a for the screw member 127 with the heating member 128, a temperature discrepancy in the focus ring 124 can be reduced. Consequently, the uniformity of the temperature of the focus ring 124 can be improved.

### Third Exemplary Embodiment

A third exemplary embodiment is characterized in that positioning of the focus ring is achieved by forming a hole into which the lifter pin is insertion-fitted at the lower portion of the focus ring.

Since a configuration of a plasma processing apparatus according to the third exemplary embodiment is the same as the configuration of the plasma processing apparatus 100 of the first exemplary embodiment, redundant description thereof will be omitted here. In the third exemplary embodiment, a configuration of a mounting table 110 is different from that of the first exemplary embodiment.

FIG. 9 is a cross sectional view illustrating the configuration of the mounting table 110 according to the third exemplary embodiment. In FIG. 9, the same parts as those of FIG. 3 will be assigned same reference numerals, and redundant description will be omitted.

As illustrated in FIG. 9, in the third exemplary embodiment, a hole 124a having a bottom is formed at the lower portion of the focus ring 124. The lifter pin 182 is insertion-fitted into the hole 124a having the bottom. That is, the lifter pin 182 is raised from a state where it is retreated to the lowest position along the insertion hole 116a up to a position higher than the peripheral region 116 of the base 114, and is insertion-fitted into the hole 124a having the bottom.

As stated above, according to the third exemplary embodiment, the lifter pin 182 is insertion-fitted into the hole 124a having the bottom formed at the lower portion of the focus ring 124. Accordingly, the positioning of the focus ring 124 can be achieved by the lifter pin 182 while the non-uniformity of the temperature of the focus ring 124 is reduced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A mounting table, comprising:
a base configured to place a processing target object thereon;
a focus ring provided on the base to surround a region on which the processing target object is placed;
a connecting member provided with a through hole and configured to connect the base to a member provided below the base by being inserted into an insertion hole formed at a region of the base which corresponds to a lower portion of the focus ring; and
a lifter pin provided at the base such that the lifter pin is allowed to be protruded from the insertion hole by being inserted into the through hole of the connecting member, and configured to raise the focus ring by being protruded from the insertion hole.

2. The mounting table of claim 1,
wherein the focus ring is provided on the base with a heat transfer member, which is configured to be extended/contracted and provided with a through hole, therebetween,
the lifter pin comes into contact with the lower portion of the focus ring after passing through the through hole of the heat transfer member when the lifter pin raises the focus ring by being protruded from the insertion hole, and
the heat transfer member is extended to fill a gap between the base and the focus ring as the focus ring is raised.

3. The mounting table of claim 1, further comprising:
a heating member provided between the base and the focus ring and configured to cover, in the region of the base which corresponds to the lower portion of the focus ring, a region except the insertion hole.

4. The mounting table of claim 1,
wherein a hole having a bottom is formed at the lower portion of the focus ring, and
the lifter pin is insertion-fitted into the hole having the bottom.

5. The mounting table of claim 1, further comprising:
a coolant path formed within the base and configured to allow a coolant to pass therethrough.

6. A plasma processing apparatus, comprising:
a mounting table as claimed in claim 1.
